(19) United States
(12) Patent Application Publication
(10) Pub. No.: US 2007/0272995 A1
(43) Pub. Date: Nov. 29, 2007

(54) Photosensitive device

(76) Inventors: Ya-Chin King, Taipei City (TW); Chrong-Jung Lin, Hsinchu City (TW)

Correspondence Address: BIRCH STEWART KOLASCH & BIRCH, PO BOX 747, FALLS CHURCH, VA, 22040-0747, US

(21) Appl. No.: 11/802,369

(22) Filed: May 22, 2007

(30) Foreign Application Priority Data
May 23, 2006 (TW) 95118327

(51) Int. Cl. H01L 31/00

(52) U.S. Cl. 257/440

(57) ABSTRACT

A photosensitive device is provided. The photosensitive device can be an image sensor or a solar cell. The photosensitive device includes a driving circuit such as photo sensor circuit or solar cell circuit, and a nano-crystal layer. The nano-crystal layer is located above the driving circuit and includes a silicon compound layer and plural nano-crystal particles. The nano-crystal particles are distributed in the silicon compound layer and capable of capturing photon and further converting into photocurrent.

### RELATED APPLICATIONS

This application claims priority to Taiwan Application Serial Number 95118327, filed May 23, 2006, which is herein incorporated by reference.

### BACKGROUND

1. Field of Invention

The present invention relates to a photosensitive device. More particularly, the present invention relates to an image sensor and a solar cell.

2. Description of Related Art

CMOS image sensor (CIS) device is featured by lower operating voltage, lower power consumption and higher operating efficiency than that of a charge couple device (CCD). Besides, CIS device can be produced in CMOS manufacturing process, so CIS device is widely applied in video phone, digital camera, mobile phone and aerospace industry.

Referring to FIG. 1A, a conventional CIS device is shown. The CIS device includes a photo diode D and three MOS transistor M1, M2, and M3. Transistor M1 can be a switch device, and the photo diode D is connected with the transistor M1. When the transistor M1 is ON, the photo diode D receives a reverse bias voltage from the electric source VDD. The photo diode D starts to receive light radiation when it is provided with the reverse bias voltage. The electron-hole pairs are generated in the photo diode D, and the amount of electron-hole pairs thereof are determined by the intensity of light radiation. The electric signal generated by the electron-hole pair thereof is further amplified by the transistor M2 and transferred to the transistor M3. The electric signal is transferred from the source electrode of the transistor M3 to a signal processor, when a readout signal is provided to the gate electrode of transistor M3.

Referring to FIG. 1B, a vertical view of a pixel of a conventional CIS device is shown. A pixel region 102 is formed on a p-type substrate 100. The pixel region 102 includes a photo diode region 104 and an active region 105. The photo diode region 104 includes an N well 106 located on the p-type substrate 100. A depletion region 108 is formed on the junction of the p-type substrate 100 and the N well 106. The N well 106 and the p-type substrate 100 receive a positive voltage and a negative voltage respectively. The active region 105 includes three transistors 112a, 112b, and 112c. The structure and the function of the transistors 112a, 112b and 112c similar to the transistors M1, M2 and M3 in FIG. 1A are used for operating of the photo diode region 104.

The active region 105 of the conventional CIS device given above is located on the same plane with the photo diode region 104. Such structure further reduces the aperture ratio of the pixel of the CIS device. Besides, the active region 105 of the conventional CIS device given above is sensitive to light radiation. Hence, an unfavorable photocurrent is generated in the active region 105 when the active region 105 receives a light radiation at the same time with the photo diode 104. The photosensitivity of CIS device is decreased as a result of unfavorable photocurrent. Therefore, it is necessary to develop a new CIS device having a preferable circuit allocation.

### SUMMARY

An image sensor is provided. The image sensor includes plural pixels. Each of the pixels includes a substrate, a photo sensor circuit and a photo sensor. The photo sensor circuit is located on the substrate. The photo sensor is located above and electrically connected with the photo sensor circuit. The photo sensor includes a bottom electrode, a nano-crystal layer and a transparent electrode. The bottom electrode is located above the photo sensor circuit. The nano-crystal layer is located on the bottom electrode and includes a silicon compound layer and plural nano-crystal particles. The nano-crystal particles are distributed in the silicon compound layer and capable of capturing photon and further converting into photocurrent. The transparent electrode is located on the nano-crystal layer.

A solar cell is provided. The solar cell includes a substrate, a solar cell circuit and a solar cell device. The solar cell circuit is located on the substrate. The solar cell device is located above and electrically connected with the solar cell circuit. The solar cell device includes a first electrode, a nano-crystal layer and a second electrode. The first electrode is located above the solar cell circuit. The nano-crystal layer is located on the first electrode. The nano-crystal layer includes a silicon compound layer and plural nano-crystal particles. The nano-crystal particles are distributed in the silicon compound layer and capable of capturing photon and further converting into photocurrent. The second electrode is located on the nano-crystal layer.

An apparatus having a solar cell as a chargeable source is provided. The apparatus includes a chargeable device, a solar cell given above and a charger circuit. The solar cell is used for supplying power to the chargeable device. The charger circuit is electrically connected with the chargeable device and the solar cell. The charger circuit is capable of controlling the power supplied from the solar cell to the chargeable device.

### BRIEF DESCRIPTION OF THE DRAWINGS

These and other features, aspects, and advantages of the present invention will become better understood with regard to the following description, appended claims, and accompanying drawings where:

FIG. 1A shows a conventional CMOS image sensor (CIS) device.

FIG. 1B is a vertical view showing a pixel of the conventional CIS device in FIG. 1A.

FIG. 2A shows a vertical view of an image sensor according to one embodiment of the present invention.

FIG. 2B is a cross-sectional view showing a pixel of the image sensor in FIG. 2A.

FIG. 2C is a cross-sectional view showing an operation of the image sensor according to the embodiment of the present invention.

FIG. 2D is a cross-sectional view showing one pixel including a color filter.

FIG. 3A shows a cross-sectional view of a solar cell similar with the image sensor in FIG. 2A according to another embodiment of the present invention.

FIG. 3B shows an apparatus having a solar cell 300 as a chargeable source.

FIG. 4A shows a photo response of the silicon nano-crystal image sensor compared with a conventional image sensor including PIN (positive-intrinsic-negative) diode.

FIG. 4B shows a spectrum-response of the silicon nano-crystal image sensor including a silicon nano-crystal layer with different refractive index over whole visible light spectrum from 400 nm to 700 nm.

FIG. 4C shows a spectrum-response of the silicon nano-crystal image sensor including a silicon nano-crystal layer with different thickness over whole visible light spectrum from 400 nm to 700 nm.

FIG. 4D shows photosensitivity and dark current of the silicon nano-crystal image sensor including the silicon nano-crystal layer with different refractive index.

FIG. 4E shows photosensitivity and dark current of the silicon nano-crystal image sensor including the silicon nano-crystal layer with different thickness.

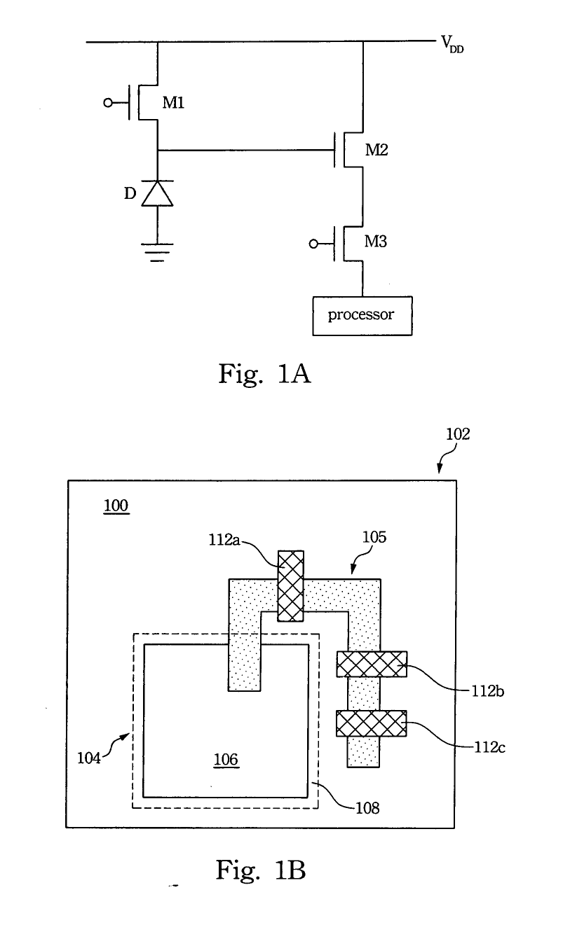

### DETAILED DESCRIPTION

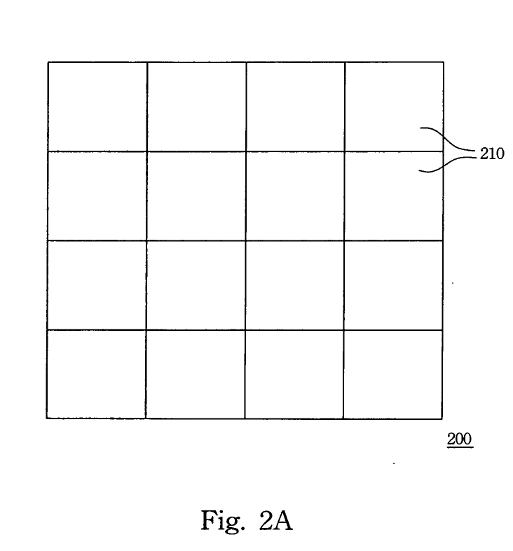

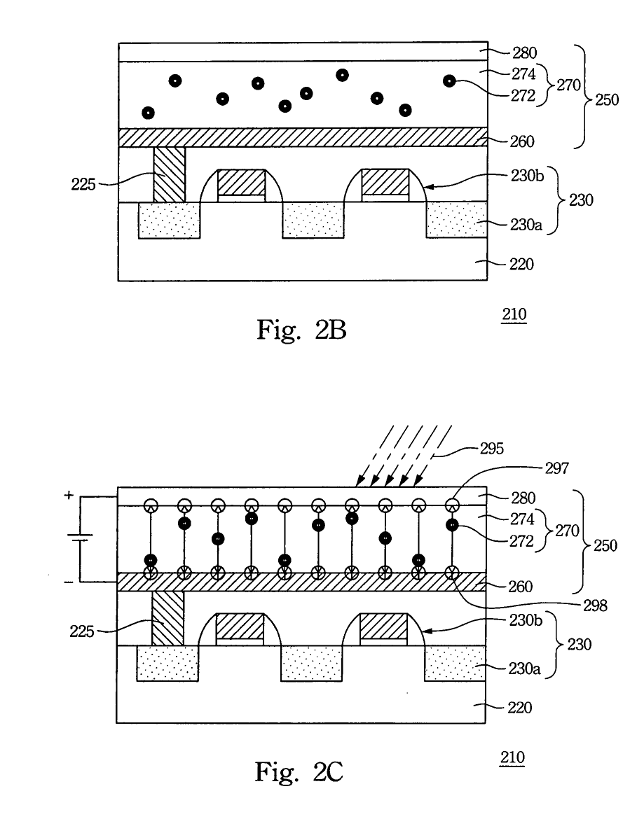

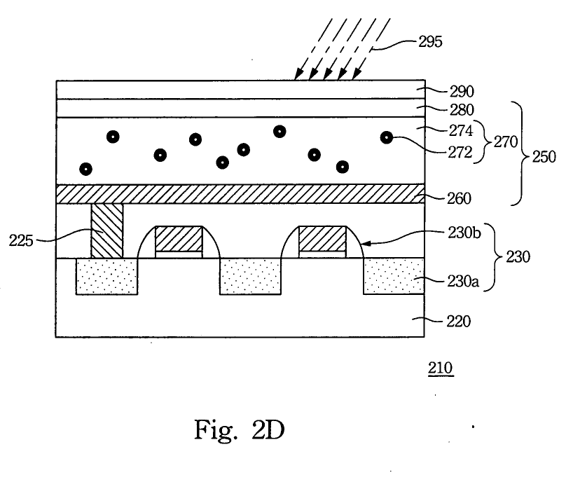

FIG. 2A shows a vertical view of an image sensor according to one embodiment of the present invention. The image sensor 200 includes plural pixels 210. Please referring to FIG. 2B, a cross-sectional view of one pixel 210 is shown. The pixel 210 includes a substrate 220, a photo sensor circuit 230 and a photo sensor 250. The photo sensor circuit 230 is located on the substrate 220. The photo sensor 250 is located above and electrically connected with the photo sensor circuit 230.

The photo sensor 250 includes a bottom electrode 260, a nano-crystal layer 270 and a transparent electrode 280. The bottom electrode 260 is located above the photo sensor circuit 230. The nano-crystal layer 270 is located on the bottom electrode 260. The nano-crystal layer 270 includes a silicon compound layer 274 and plural nano-crystal particles 272. The nano-crystal particles 272 are distributed in the silicon compound layer 274, and capable of capturing photon and further converting into photocurrent. The transparent electrode 280 is located on the nano-crystal layer 270.

FIG. 2C is a cross-sectional view showing an operation of the image sensor according to the embodiment of the present invention. Referring to FIG. 2C, when light radiation 295 passes through the transparent electrode 280 and transmits to the photo sensor 250, plural electrons 297 and holes 298 are generated in the nano-crystal layer 270. When an electric field is applied to the photo sensor 250, the electrons 297 and the holes 298 are moved to the transparent electrode 280 and the bottom electrode 260 respectively, and an electric signal is generated. The electric signal is analyzed in a signal processor to determine the intensity of light radiation 295.

FIG. 2D is a cross-sectional view showing one pixel including a color filter. Referring to FIG. 2A and FIG. 2D, the color filter 290 is located on the transparent electrode 280. The color filter 290 can be a combination of the red color, green color and blue color photo resist. When the image sensor 200 is used to capture an image, the light radiation 295 passes through the color filters 290 and filters into red, green and blue lights respectively. The red, green and blue lights are radiated to the nano-crystal layer 270 and converted to different current signals. The different current signals thereof are processed in the signal processor to restore the original image captured by the image sensor 200.

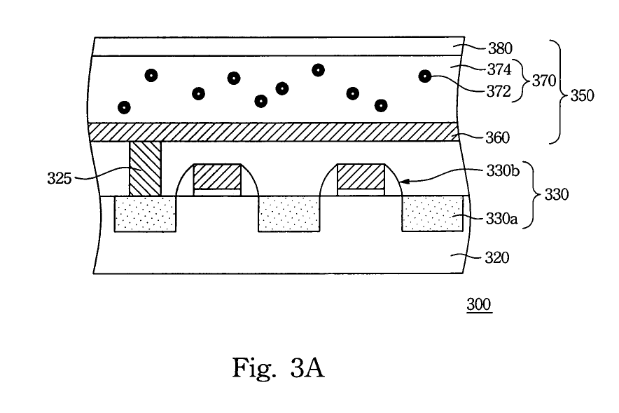

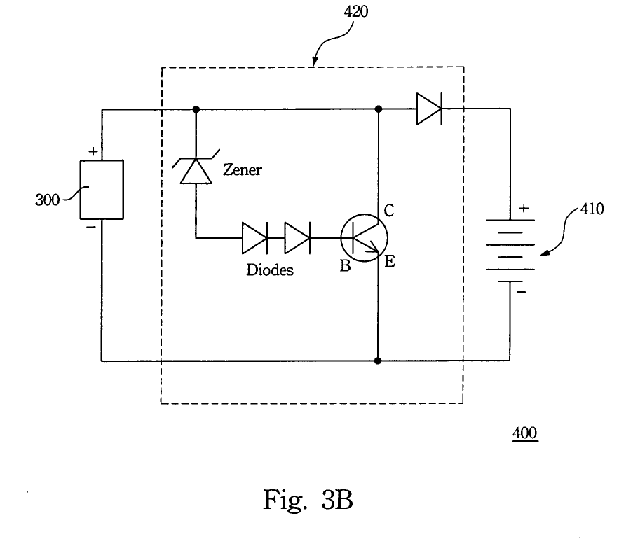

Referring to FIG. 3A, a cross-sectional view of a solar cell similar to the image sensor in FIG. 2A according to another embodiment of present invention is shown. The solar cell 300 includes a substrate 320, a solar cell circuit 330 and a solar cell device 350. The solar cell circuit 330 is located on the substrate 320. The solar cell device 350 is located above and electrically connected with the solar cell circuit 330.

Referring to FIG. 3A, the solar cell device 350 includes a first electrode 360, a nano-crystal layer 370 and a second electrode 380. The first electrode 360 can be a transparent or opaque electrode, and located above the solar cell circuit 330. The composition of the nano-crystal layer 370 is the same with the nano-crystal layer 270 described in FIG. 2B and located on the first electrode 360. The second electrode 380 is located on the nano-crystal layer 370. The second electrode 380 is a transparent electrode for allowing light radiation to pass it and travel to the nano-crystal layer 370.

Referring to FIG. 2B and FIG. 3A, the photo sensor circuit 230 and the solar cell circuit 330 given above are located under the photo sensor 250 and solar cell device 350 respectively. Therefore, the aperture ratio of the image sensor 200 or the solar cell 300 can be larger.

Referring to FIG. 2B and FIG. 3A, a plug 225 (or 325) is located between the photo sensor circuit 230 (or solar cell circuit 330) and the photo sensor 250 (or solar cell device 350). The plug 225 (or 325) can electrically connect the source/drain electrode 230a (or 330a) of transistor in the photo sensor circuit 230 (or solar cell circuit 330) and bottom electrode 260 of photo sensor 250 (or first electrode 360 of solar cell device 350). The gate electrode 230b (or 330b) of transistor in the photo sensor circuit 230 (or solar cell circuit 330) can be a switch for controlling transistor in the photo sensor circuit 230 (or solar cell circuit 330). The photo sensor circuit 230 or solar cell circuit 330 given above can be any practicable circuit.

Referring to FIG. 2B and FIG. 3A, the silicon compound layer 274 (374) can be a silicon oxide layer, a silicon nitride layer or a silicon oxynitride layer. The thickness of the silicon compound layer 274 (374) is about 50˜5000 nm. The size of each nano-crystal particles 272 (372) is about 2˜15 nm. Each nano-crystal particle 272 (372) is selected from a group consisting of silicon, germanium, tin and gallium arsenic. The nano-crystal particles 272 (372) can be formed by an ion-implantation process followed by an annealing process. The dopant concentration and the ion implantation energy are determined by the thickness of the silicon compound layer 274 (374). For example, the dopant concentration can be 1×10¹⁶˜5×10¹⁶/cm², the ion implantation energy can be 3 Kev˜1 Mev. Besides, the silicon compound layer 274 (374) also can be formed by a chemical vapor deposition process followed by an annealing process.

Referring to FIG. 2C, the bottom electrode 260 can be an opaque electrode such as metal or polysilicon electrode. When the light radiation 295 transmits to the photo sensor 250 and passes through the nano-crystal layer 270, the opaque electrode 260 is capable of reflecting the light radiation back to the nano-crystal layer 2, v preventing the light radiation 295 radiating to the photo sensor circuit 230. Therefore, the electric signal generated from the light radiation can be further increased and the unfavorable noise signal generated by the photo sensor circuit 230 due to the light radiation 295 can be reduced. It will further improve the photo sensitivity of the photo sensor 250.

Referring to FIG. 2B and FIG. 3A, the material of the transparent electrode 280 (or second electrode 380) given above can be indium tin oxide (ITO) or zinc oxide. The thickness of zinc oxide electrode is about 20˜800 nm, so that sufficient transparency can be obtained for light penetration. The first electrode 360 can be an opaque electrode such as a polysilicon electrode or a metal electrode, or a transparent electrode such as ITO or zinc oxide electrode.

Referring to FIG. 3B, an apparatus having a solar cell as a chargeable source is shown. The apparatus 400 includes a chargeable device 410, a solar cell 300 given above and a charger circuit 420. The chargeable device 410 can be a charger or a rechargeable battery. The solar cell 300 is used for supplying power to the chargeable device 410. The charger circuit 420 is electrically connected with the chargeable device 410 and the solar cell 300. The charger circuit 420 is capable of controlling the power supplied from the solar cell 300 to the chargeable device 410.

Silicon Nano-Crystal Image Sensor

A silicon nano-crystal image sensor according to embodiment described in FIGS. 2A-2C is provided. The nano-crystal layer is a silicon nano-crystal layer including a silicon compound layer and plural nano-crystal silicon particles. The transparent electrode is an ITO electrode. The bottom electrode is a metal electrode.

The silicon nano-crystal layer is formed by a plasma enhance chemical vapor deposition (PECVD) process followed by a post laser annealing process. During the PECVD process, the ratio of SiH₄ and N₂O is adjusted to obtain a desirable range of refractive index, which indicates the level of Si richness in the film. By proper post laser annealing (e.g 40˜300 mJ/cm² annealing energy), the excess of silicon atoms are segregated, clustered, and turned into nano-crystal silicon. The refractive index of the silicon nano-crystal layer is from 1.6 to 2.4. The thickness of the silicon nano-crystal layer is from 100 nm to 500 nm.

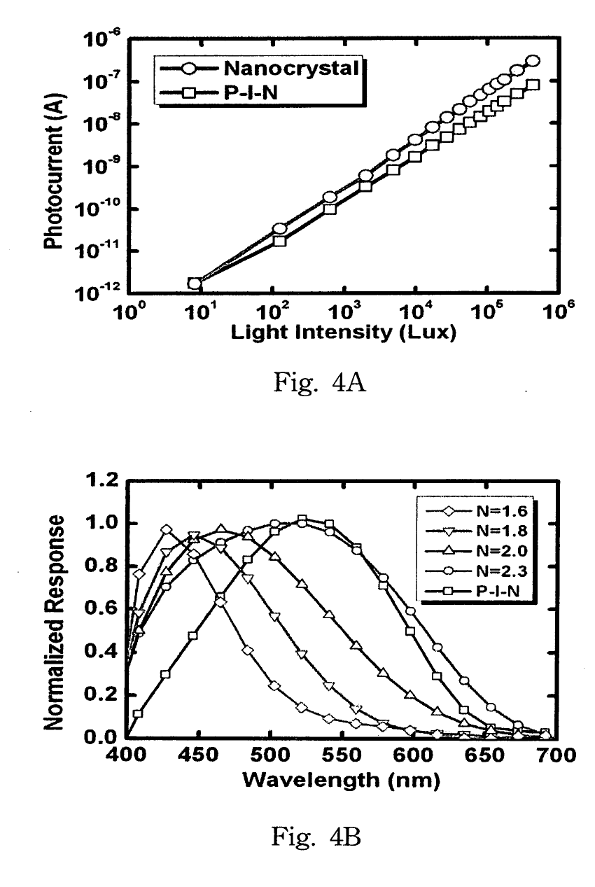

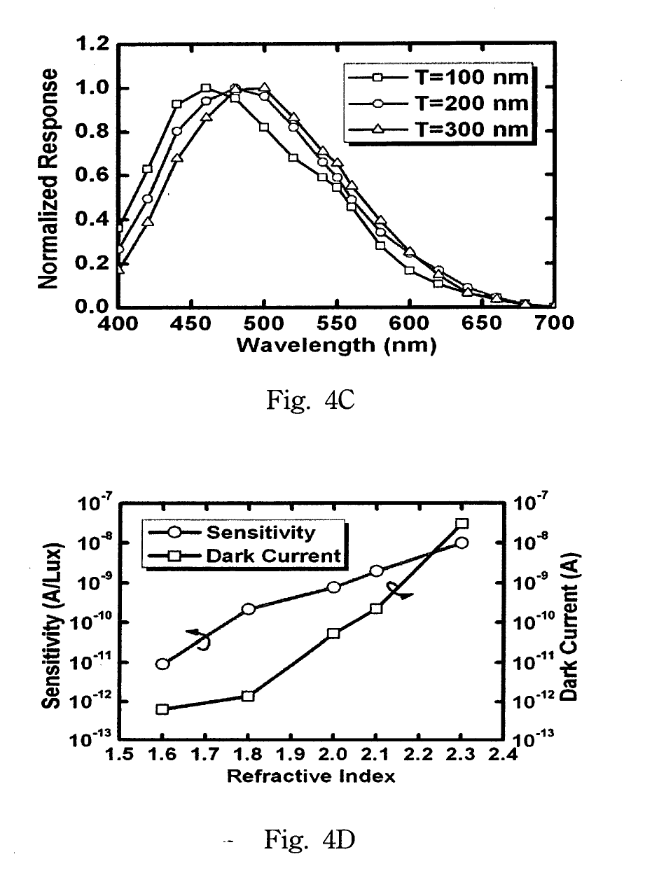

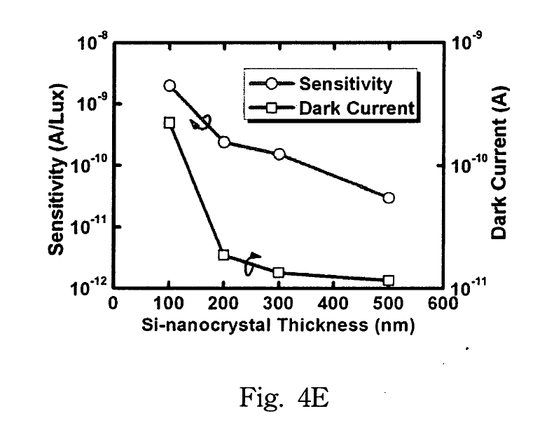

Referring to FIG. 4A, a photo response of the silicon nano-crystal image sensor compared with a conventional image sensor including PIN (positive-intrinsic-negative) diode is shown. The refractive index and the thickness of the silicon nano-crystal layer is 1.8 and 100 nm. The silicon nano-crystal image sensor in the embodiment provides higher photosensitivity than conventional image sensor including PIN diode.

Referring to FIG. 4B, a spectrum-response of the silicon nano-crystal image sensor including a silicon nano-crystal layer with different refractive index over whole visible light spectrum from 400 nm to 700 nm is shown. The thickness of the silicon nano-crystal layer is about 100 nm. The peak of photo response shifts from short wavelength to long wavelength as the refractive index of the nano-crystal layer increases.

Referring to FIG. 4C, a spectrum-response of the silicon nano-crystal image sensor including a silicon nano-crystal layer with different thickness over whole visible light spectrum from 400 nm to 700 nm is shown. The refractive index of the silicon nano-crystal layer is 2.0. The spectrum-response shifts slightly from short wavelength to long wavelength as the thickness of the silicon nano-crystal layer increases.

Referring to FIG. 4D, the photosensitivity and dark current of the silicon nano-crystal image sensor including the silicon nano-crystal layer with different refractive index is shown. The thickness of the silicon nano-crystal layer is about 100 nm. Both photosensitivity and dark current of the silicon nano-crystal image sensor increase as the refractive index of the silicon nano-crystal layer increases.

Referring to FIG. 4E, the photosensitivity and dark current of the silicon nano-crystal image sensor including the silicon nano-crystal layer with different thickness is shown. The refractive index of the silicon nano-crystal layer is about 1.8. Both photosensitivity and dark current decrease as the thickness of the silicon nano-crystal layer increases.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An image sensor, comprising a plurality of pixels, each of the pixels comprising:
a substrate;
a photo sensor circuit located on the substrate; and
a photo sensor, located above and electrically connected with the photo sensor circuit, wherein the photo sensor comprises:
a bottom electrode located above the photo sensor circuit;
a nano-crystal layer located on the bottom electrode, wherein the nano-crystal layer comprises:
a silicon compound layer; and
a plurality of nano-crystal particles distributed in the silicon compound layer and being capable of capturing photon and further converting into photocurrent; and
a transparent electrode located on the nano-crystal layer.

2. The image sensor of claim 1, wherein the bottom electrode is an opaque electrode capable of reflecting the light radiation back to the nano-crystal layer.

3. The image sensor of claim 2, wherein the material of the opaque electrode is metal or poly-silicon.

4. The image sensor of claim 1, wherein the silicon compound layer is selected from a group consisting of a silicon oxide layer, a silicon nitride layer and a silicon oxynitride layer.

5. The image sensor of claim 1, wherein the particle size of each nano-crystal particle is from about 2 nm to about 15 nm.

6. The image sensor of claim 1, wherein each of the nano-crystal particles is selected from a group consisting of silicon, germanium, tin and gallium arsenic.

7. The image sensor of claim 1, wherein each of the nano-crystal particles is nano-crystal silicon.

8. The image sensor of claim 7, wherein the refractive index of the nano-crystal layer is from 1.6 to 2.4.

9. The image sensor of claim 7, wherein the thickness of the nano-crystal layer is from 100 nm to 500 nm.

10. The image sensor of claim 1, wherein the material of the transparent electrode is indium tin oxide or zinc oxide.

11. The image sensor of claim 1, further comprising a color filter, located on the transparent electrode.

12. A solar cell, comprising:
a substrate;
a solar cell circuit located on the substrate; and
a solar cell device, located above and electrically connected with the solar cell circuit, wherein the solar cell device comprises:
a first electrode located above the solar cell circuit;
a nano-crystal layer located on the first electrode, wherein the nano-crystal layer comprises:
a silicon compound layer; and
a plurality of nano-crystal particles distributed in the silicon compound layer and being capable of capturing photon and further converting into photocurrent; and
a second electrode located on the nano-crystal layer.

13. The solar cell of claim 12, wherein the silicon compound layer is selected from a group consisting of a silicon oxide layer, a silicon nitride layer and a silicon oxynitride layer.

14. The solar cell of claim 12, wherein the particle size of each nano-crystal particle is from about 2 nm to about 15 nm.

15. The solar cell of claim 12, wherein each of the nano-crystal particles is selected from a group consisting of silicon, germanium, tin and gallium arsenic.

16. The solar cell of claim 12, wherein each of the nano-crystal particles is nano-crystal silicon.

17. The solar cell of claim 16, wherein the refractive index of the nano-crystal layer is from 1.6 to 2.4.

18. The solar cell of claim 16, wherein the thickness of the nano-crystal layer is from 100 nm to 500 nm.

19. The solar cell of claim 12, wherein the second electrode is a transparent electrode.

20. An apparatus having a solar cell as a chargeable source, comprising:
a chargeable device;
a solar cell used for supplying power to the chargeable device, the solar cell comprising:
a substrate;
a solar cell circuit located on the substrate; and
a solar cell device, located above and electrically connected with the solar cell circuit, wherein the solar cell device comprises:
a first electrode located above the solar cell circuit;
a nano-crystal layer located on the first electrode, wherein the nano-crystal layer comprises:
a silicon compound layer; and
a plurality of nano-crystal particles distributed in the silicon compound layer and being capable of capturing photon and further converting into photocurrent; and
a second electrode located on the nano-crystal layer;
a charger circuit electrically connected with the chargeable device and the solar cell, and capable of controlling the power supplied from the solar cell to the chargeable device.
